(19) United States
(12) Patent Application Publication
(10) Pub. No.: US 2012/0187540 A1
(43) Pub. Date: Jul. 26, 2012

(54) METAMORPHIC SUBSTRATE SYSTEM, METHOD OF MANUFACTURE OF SAME, AND III-NITRIDES SEMICONDUCTOR DEVICE

(75) Inventors: Stewart Edward HOOPER, Oxford (GB); Valerie BERRYMAN-BOUSQUET, Oxford (GB)

(73) Assignee: SHARP KABUSHIKI KAISHA, Osaka (JP)

(21) Appl. No.: 13/348,724

(22) Filed: Jan. 12, 2012

(30) Foreign Application Priority Data
Jan. 20, 2011 (GB) 1100974.3

(51) Int. Cl. H01L 29/20; H01L 21/20

(52) U.S. Cl. 257/615; 438/478; 257/E29.089; 257/E21.09

(57) ABSTRACT

A laminated substrate system containing a metamorphic transition region (2) made from multiple and alternating layers of AlₓGa₁₋ₓN (5) and the supporting substrate material (4) (or a material having the same general chemical composition thereto). A III-Nitrides semiconductor device (2) with a low dislocation density is formed on top of the laminated substrate system. The multiple layers (4,5) of the metamorphic transition region form a superlattice structure whose lattice constant and structure changes along its growth direction from that of the supporting substrate (1) (in the vicinity of the supporting substrate) to that of the device (3) (in the vicinity of the device).

This Nonprovisional application claims priority under 35 U.S.C. §119(a) on Patent Application No. 1100974.3 filed in the United Kingdom on Jan. 20, 2011, the entire contents of which are hereby incorporated by reference.

### FIELD OF THE INVENTION

The present invention relates to a substrate structure, and in particular to a substrate structure for a III-Nitride materials system such as, for example, the (Al,Ga,In)N materials system. The present invention also relates to a method of manufacture of a substrate structure, and in particular to manufacture of a substrate structure for the III-Nitride materials system such as, for example, the (Al,Ga,In)N materials system. The invention also relates to a III Nitride semiconductor device incorporating a substrate system of the invention—a substrate system of the invention may be applied as a substrate for the manufacture of an optoelectronic semiconductor device such as a light emitting diode (LED), laser diode (LD) and solar cell, or an electronic semiconductor device such as a heterostructure field effect transistor (HFET) or a high electron mobility transistor (HEMT).

By (Al,Ga,In)N is meant a compound of the general formula AlₓGa_{y}In_{(1-x-y)}N, where 0≦x≦1 and 0≦y≦1. For convenience the indexes x and y may be omitted so that, for example, AlGaInN denotes a compound having non-zero mole fractions of Al, Ga and In, AlGaN denotes a compound having non-zero mole fractions of Al and Ga and a zero mole fraction of In, and so on.

### BACKGROUND OF THE INVENTION

Due to its hexagonal crystal structure, low cost, good availability and physical robustness, sapphire (a crystalline form of aluminium oxide, Al₂O₃) is currently the substrate of choice on which to form high brightness blue LEDs made from III-Nitride semiconductors. However, it is by no means perfect for this application because even though sapphire and III-Nitrides are from the same hexagonal crystal family they have different crystal systems and a foreign crystal chemistry relationship, i.e. sapphire is classed as a foreign substrate for III-Nitride semiconductors. (Crystals are classed into 7 different crystal systems according to their symmetries; in three dimensions there are seven crystal systems, namely: triclinic, monoclinic, orthorhombic, tetragonal, trigonal, hexagonal, and cubic.) Blue LED devices grown on sapphire suffer from having a very high density of threading dislocations typically greater than 10⁸ cm⁻², which in-turn leads to a drop-off in device efficiency. The formation of these dislocations is mainly due to the 14% difference in lattice size between GaN and sapphire.

Low temperature grown AlN or GaN buffer layers are typically employed by the LED industry as a way to partially overcome the lattice difference between GaN and sapphire. For example U.S. Pat. No. 4,855,249 proposes growing AlGaN films over a sapphire substrate according to a technique in which an AlN buffer layer is initially grown over the substrate, and U.S. Pat. No. 5,290,393 proposes the use of an AlN, GaN or GaAlN buffer layer on a sapphire substrate. However, a very high density of threading dislocations are still generated.

The formation of blue LEDs on silicon substrates also suffers from the same issues but to a much greater degree due to their vastly different crystal systems and foreign crystal chemistry relationship.

In several other III-V material systems where the device layers are mismatched from the substrate, e.g. InAlAs transistors, a metamorphic buffer layer is employed to prevent dislocations from threading into the device. A metamorphic buffer layer can be described as an intermediate region which is disposed between a substrate and one or more device layers and hosts a gradual change in crystal lattice size between the substrate and the device layers or, more precisely, it gradually converts the substrate lattice size into the device lattice size. For example, U.S. Pat. No. 3,862,859 proposes a semiconductor device in which an intervening layer is provided between a substrate and a device layer. The intervening layer is formed from a material having substantially the same lattice constant as the device layer, and the growth of the intervening layer is interrupted so that the intervening layer is made up of a plurality of epitaxial layers with a growth interface being present between each pair of adjacent layers. U.S. Pat. No. 3,862,859 proposes that each of the layers will have fewer dislocations than the previous layer. As a further example U.S. Pat. No. 6,818,928 proposes the use of a metamorphic III-V semiconductor buffer layer on a III-V substrate such as GaAs. The buffer layer has a compositionally graded quaternary lower portion (for example compositionally graded AlGaInAs) and a compositionally graded ternary upper portion (for example compositionally graded AlInAs) to reduce threading dislocations by grading the lattice size of the buffer layer. These prior arts are applied only to lattice mismatched materials that have the same crystal system (e.g. zinc blende).

U.S. Pat. No. 4,088,515 proposes a GaAs/GaAsP superlattice structure grown over a substrate. The average lattice parameter of the superlattice is matched with the average lattice parameter of the substrate on which the superlattice buffer layer is grown, so that misfit dislocations are not generated between the superlattice and the substrate.

There are reports on the use of a thin layer of Al₂O₃ between another foreign substrate and a III-Nitride LED device structure to reduce threading dislocations and improve device efficiency (JJAP 43, 1930-1933 2004 and APL 94, 222105, 2009). However, such interlayers do not alter the in-plane lattice parameter or act like a metamorphic layer.

U.S. Pat. No. 7,244,520 proposes a substrate for growth of a nitride semiconductor that is formed of a sapphire base substrate and the following layers grown over the sapphire base substrate: an aluminium oxide layer, an aluminium oxynitride layer, an aluminium nitride layer, and an aluminium oxide cap layer. The use of an aluminium oxynitride buffer layer is also proposed in U.S. Pat. Nos. 6,744,076 and 5,741,724. U.S. Pat. No. 6,744,076 proposes heating a sapphire substrate in the presence of carbon, nitrogen and carbon monoxide to form an aluminium oxynitride layer and an aluminium nitride film over the sapphire substrate. U.S. Pat. No. 5,741,724 proposes a growing a plurality of buffer layers over a spinel (MgAl₂O₄) substrate; the buffer layers include a first buffer layer formed of aluminium oxynitride, a second buffer layer formed of a plurality of compositionally graded aluminium oxynitride layers, a third buffer layer formed of aluminium nitride, and a fourth buffer layer formed of gallium nitride. These proposals have the disadvantage that they require the use of aluminium oxynitride which tends to have poor crystallinity.

US 2006/0273300 proposes a GaN-based device grown over a sapphire substrate. An n-GaN contact layer is grown over the substrate, and a lower cladding region, a lower waveguiding layer, an active layer, an upper waveguiding layer and an upper cladding region are then grown. One or both cladding regions could be formed of a layer structure, for example of alternately stacked AlGaN layers and GaN layers, to allow good optical confinement without a large resistance to carrier injection.

DE 10032062 proposes a gas sensor having a HEMT structure in which a plurality of layers formed from a group III nitride hetrostructure, such as a GaN/AlGaN/AlN hetrostructure are disposed over a sapphire substrate. This document is directed to improving the performance of the gas sensor.

US 2010/0237387 proposes a buffer region between a substrate (silicon, silicon carbide or sapphire) and a nitride semiconductor layer. The proposed buffer region proposed in this document has a first region of layers of alternating composition, and a second region of layers of alternating composition. The layers of alternating composition layers are different members of the AlMGaN layer, where M is indium or boron.

JP 2010-232610 relates to improving the performance of a GaN/AlGaN HEMT that is formed over a substrate (silicon, silicon carbide or sapphire). The document proposes an AlN or GaN buffer layer formed over the substrate, and a GaN layer and an AlGaN layer are then grown over the buffer layer.

### OBJECT OF THE INVENTION

It is an object of the invention to address at least some of the problems encountered in growing one or more layers of III-Nitride semiconductor material(s) over a foreign substrate such as sapphire, GaAs, silicon or silicon carbide.

### SUMMARY OF INVENTION

A first aspect of the present invention provides a substrate system comprising: a substrate made of material M; and a metamorphic transition region disposed on a surface of the substrate, the metamorphic transition region including a plurality of alternating layers of AlₓGa₁₋ₓ,N (0≦x≦1) and a material having the same general chemical composition as the substrate material M.

As explained above, a metamorphic transition region is a region disposed over the substrate and that, when one or more device layers are grown over the substrate system, will be an intermediate region disposed between the substrate and the one or more device layers, and will host a gradual change in crystal lattice size between the substrate and the device layer(s) (or will gradually “convert” the substrate lattice size into the device lattice size). A substrate system that includes a substrate and such a metamorphic transition region that contains a plurality of alternating layers of AlₓGa₁₋ₓN (0≦x≦1) and a material having the same general chemical composition as the substrate material is not taught in the prior art.

The embodiment shown in FIG. 4 of U.S. Pat. No. 7,244,520 describes the case whereby the aluminium oxynitride layer is absent from the substrate structure, i.e. a substrate composed of a sapphire base substrate: an aluminium oxide layer, an aluminium nitride layer, and an aluminium oxide cap layer is proposed. Such a structure cannot be classed as containing a metamorphic transition region since it is not possible to produce a gradual change in lattice parameter using a single aluminium nitride-aluminium oxide layer pair.

In US 2006/0273300 the layer structure is provided in a cladding layer to allow good optical confinement without a large resistance to carrier injection, and the layer structure does not form part of the “substrate system” of the device. Furthermore, the layer structure of US 2006/0273300 does not include a layer of a material having the same general chemical composition as the substrate material. The substrate in US 2006/0273300 is a sapphire substrate, but there is no suggestion of using an aluminium oxide layer in the cladding layer (or anywhere else in the device structure).

In DE 10032062 the layers structure forms the HEMT device structure itself, and is not a metamorphic buffer layer. Moreover, there no reference in DE 10032062 to the use of layers having the same general composition as the substrate—the substrate is sapphire, but there is no reference to using an aluminium oxide layer in the layer structure.

US 2010/0237387 proposes a buffer region that has a first region of layers of alternating composition, and a second region of layers of alternating composition. The substrate is silicon, silicon carbide or sapphire, and the layers are different members of the AlMGaN layer, where M is indium or boron. There is no suggestion of using layers having the same general composition as the substrate in the buffer region.

JP 2010-232610 relates to improving the performance of a GaN/AlGaN HEMT by forming an buffer layer over the substrate. There is no suggestion of using a metamorphic transition region including a plurality of layers of a material having the same general chemical composition as the substrate material—JP 2010-232610 uses a silicon, silicon carbide or sapphire substrate, but the buffer layer is an AlN or GaN buffer layer

The invention thus provides an improved method of preventing, or at least reducing, threading dislocations forming in a device (such as a blue LED) fabricated in the (Al,Ga,In)N materials system over a substrate such as a sapphire or silicon substrate is highly desirable. By minimising or eliminating dislocations from threading into a device grown on top of a supporting substrate, the efficiency of the device is thereby improved.

The invention provides a way of forming, for example, a high efficiency blue LED device structure on a foreign supporting substrate by using a metamorphic transition region grown between the supporting substrate and device to eliminate or dramatically reduce the number of dislocations threading into in the device.

The invention describes a substrate system whereby a foreign supporting substrate, such as sapphire or silicon, is “converted” into a nitride material such as GaN, AlN or AlGaN by growing a metamorphic transition region which gradually grades the lattice size and structure, from the lattice size and structure of the substrate to the lattice size and structure of the nitride material. By grading the lattice size and structure, the formation of threading dislocations can be dramatically reduced through relaxing any strain and preventing the formation and coalescence of 3D islands. The metamorphic transition region material can be graded through the use of different alternating layers made of the supporting substrate material (e.g. Al₂O₃ or Si) on the one hand and AlₓGa₁₋ₓN on the other hand where the layer thicknesses and aluminium content (x) are varied during growth.

It should be noted that, where the invention is applied to for example a sapphire substrate, the metamorphic transition region is not required to contain layers of sapphire (which is a particular form of aluminium oxide, Al₂O₃, and which may be coloured owing to the presence of impurities) but may contain layers of Al₂O₃ for example epitaxially deposited layers of Al₂O₃. In general, the invention may be applied provided that the metamorphic transition region contain layers that have the same general chemical composition as the substrate material (eg Al₂O₃ layers and a sapphire substrate), but that differ in, for example, impurity content and/or crystal form.

The deposition of Al₂O₃ (or Silicon) and AlₓGa₁₋ₓN in a superlattice structure is not previously known in any prior art.

A second aspect of the invention provides a method of forming a substrate system comprising the steps of:

providing a substrate made of a substrate material

depositing a metamorphic transition region on the surface of the said supporting substrate, the metamorphic transition region including a plurality of alternating layers of AlₓGa₁₋ₓN (0≦x≦1) and a material having the same general chemical composition as the substrate material.

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### Effect of the Invention

Use of the metamorphic transition region defined in the first aspect of the invention makes possible a gradual change of the lattice parameter and the crystal structure through the metamorphic transition region, from the lattice parameter and crystal structure of the substrate to the lattice parameter and crystal structure of the AlₓGa₁₋ₓN material used in the metamorphic transition region. An (Al,Ga,In)N layer, or a device structure including two or more (Al,Ga,In)N layers, may be grown over the substrate system with little or no lattice mis-match to the lattice parameter of the metamorphic transition region at its upper surface. This reduces the number density of dislocations in the (Al,Ga,In)N layer(s), and so makes possible the growth of higher quality (Al,Ga,In)N layer(s) and devices.

### BRIEF DESCRIPTION OF DRAWINGS

FIG. 1 illustrates a III-Nitrides semiconductor device disposed on a foreign supporting substrate according to the invention.

FIG. 2 is a schematic view of the multilayer structure of the invention.

FIG. 3 is a schematic view of the multilayer structure of the invention according to one embodiment.

FIG. 4 is a schematic view of the multilayer structure of the invention according to another embodiment.

### DESCRIPTION OF REFERENCE NUMERALS

1 Supporting substrate
2 Metamorphic transition region
3 III-Nitrides semiconductor device
4 Constituent layer of the metamorphic transition region composed of the same material as the supporting substrate
5 Other constituent layer of the metamorphic transition region composed of AlₓGa₁₋ₓN

### DETAILED DESCRIPTION OF THE EMBODIMENTS

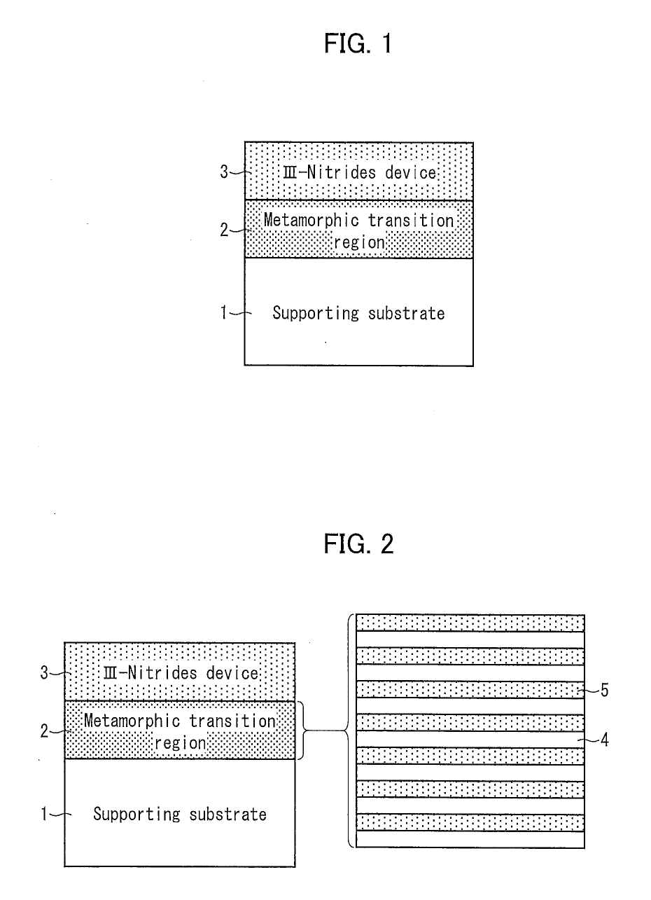

FIG. 1 illustrates the basic concept of the invention comprising of a device 3 disposed on a supporting substrate 1 with a metamorphic transition region 2 providing a region which converts the substrate crystal structure (and lattice size) into the device crystal structure (and lattice size).

FIG. 2 illustrates that the metamorphic transition region 2 is of laminated construction consisting of multiple and alternating layers 4, 5 made of material of a same general chemical composition as the supporting substrate and AlₓGa₁₋ₓN respectively. Preferably, the thickness of the alternating layers 4, 5 and the value of x varies so as to ensure that two-dimensional (2D) or layer-by-layer growth occurs for each layer 4, 5 and that the entire surface of the transition region remains smooth. The multiple layers 4, 5 preferably form a superlattice structure whose lattice constant changes, along its growth direction, from that of the supporting substrate 1 (in the vicinity of the supporting substrate) to that of the device 3 (in the vicinity of the device). The change in lattice constant is precisely controlled by the thickness of the superlattice layers and the value of x.

A III-Nitrides semiconductor device 3 is grown on the top surface of the metamorphic transition region. The device is typically an LED, LD, solar cell, HFET or HEMT (the detailed structure of the device 3 is not relevant to the invention and the device 3 is therefore shown as a single block in FIG. 2). A processing step whereby the metamorphic substrate system is mechanically separated and removed from the device structure can be implemented during the post-growth fabrication stage of the device. The supporting substrate 1 is generally a single crystal wafer that provides mechanical stability. Suitable supporting substrates are sapphire, silicon, silicon carbide, and gallium arsenide (GaAs). These substrates can be classed as foreign substrates when used for III-Nitride semiconductor devices.

One embodiment of the invention is concerned with a metamorphic substrate system for the growth of high quality III-Nitride semiconductor devices on sapphire wafers. In this case, the supporting substrate is sapphire. In order to dispose a high quality III-Nitride device on sapphire it is critical to ensure that 2D growth always occurs during the metamorphic transition region deposition and that any change of the growth surface from 2D to 3D is prevented. The suppression of 3D growth prevents the formation of threading dislocations.

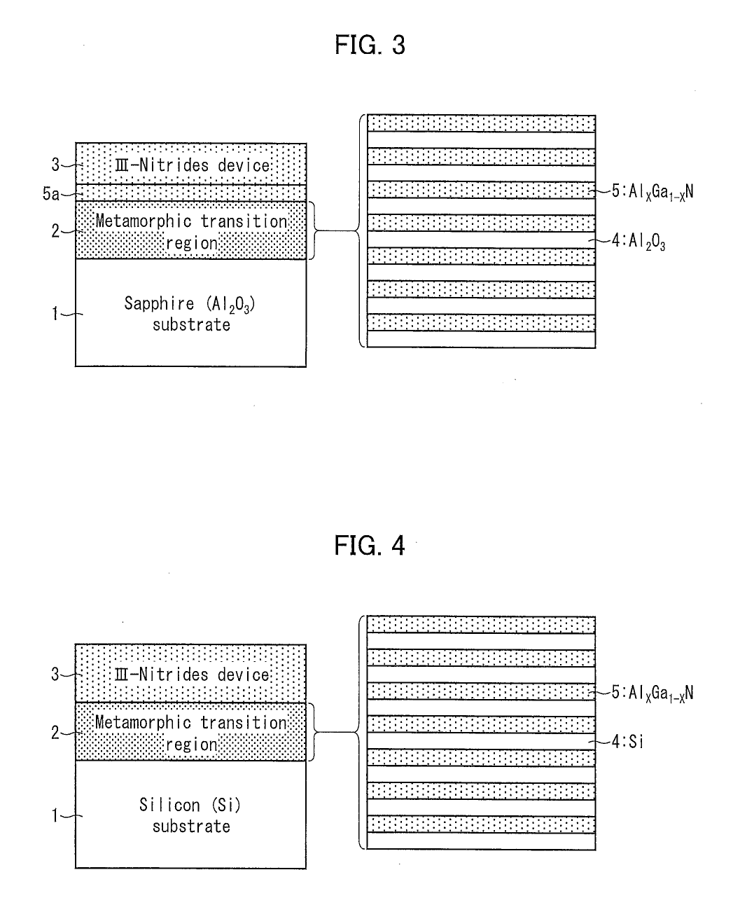

FIG. 3 illustrates the multilayer structure of the metamorphic transition region 2. It consists of a series of Al₂O₃ layers 4 alternating with AlₓGa₁₋ₓN layers 5. In the region of the supporting sapphire substrate 1, the thickness of the Al₂O₃ layers 4 is substantially greater than the AlₓGa₁₋ₓN layers 5. The difference in thickness between the alternating layers is then gradually reduced, in the direction of growth, towards the central region of the metamorphic transition region 2. Above the central region of the metamorphic transition region 2, the thickness of the AlₓGa₁₋ₓN layers 5 gradually becomes greater than the thickness of the Al₂O₃ layers 4.

Finally, in the region of the device 3, the thickness of the AlₓGa₁₋ₓN layers 5 is substantially greater than the Al₂O₃ layers 4. Varying the thickness of the alternating layers in this way, effectively grades the lattice constant throughout the metamorphic transition region. The value of x can be varied between the layers 5 in order to further control the lattice constant. A III-Nitrides semiconductor device 3 is grown on the top surface of the metamorphic substrate system.

The structure of the metamorphic substrate system is preferably completed by a further layer of AlₓGa₁₋ₓN, shown as layer 5a in FIG. 3. This further AlGaN layer 5a can be of any thickness and is separate from the transition region, i.e. it is not part of any superlattice. The layer 5a is the layer on which a device structure is grown, and to which n-type electrical contact is made in the finished device. Therefore, the layer 5a is preferably provided to allow efficient current injection through the device, because the transition region 2 itself is very likely to have a high electrical resistance. In some cases the further AlGaN layer 5a may be omitted, but current injection may then be a problem.

Where the further AlGaN layer 5a is provided, the lattice constant of the transition region adjacent to the further AlₓGa₁₋ₓN layer 5a is preferably substantially equal to the lattice constant of the further AlₓGa₁₋ₓN layer.

Since the metamorphic transition region suppresses the formation and propagation of threading dislocations in the growth direction, the number density of the threading dislocations present in the layers of the transition region decreases along the growth direction. For example the invention may provide a structure in which the upper AlₓGa₁₋ₓN layer 5a (or the uppermost AlₓGa₁₋ₓN layer 5 of the transition region 2 if the upper AlₓGa_{1-xN layer 5}a is not provided) contains fewer than 10⁷ threading dislocations per cm², or contains fewer than 10⁶ threading dislocations per cm², or even contains fewer than 10⁵ threading dislocations per cm². As a result the III-Nitrides semiconductor device 3 will contain far fewer threading dislocations than in the art, therefore high efficiency device performance will result. A number of workers have shown that internal quantum efficiency of a semiconductor device increases as the dislocation density decreases. For example, Dai et al. have shown, in “Internal quantum efficiency and non-radiative recombination coefficient of GaInN/GaN multiple quantum wells with different dislocation densities”, Appl. Phys. Lett. Vol. 94, 111109 (2009), that, for a given carrier concentration, the internal quantum efficiency of a GaInN/GaN structure increases as the density of threading dislocations decreases. Reducing the density of threading dislocations to fewer than 10⁷ threading dislocations per cm², or to fewer than 10⁶ threading dislocations per cm², or even to fewer than 10⁵ threading dislocations per cm² will therefore lead to a device with a high internal quantum efficiency.

It is not strictly necessary to grow the device 3 using the same technique as used for the metamorphic transition region 2. Also it is not strictly necessary to grow the alternating layers 4, 5 immediately in succession; growth interrupt can be provided between layers to ensure smooth interfaces between them and prevent the formation of mixed regions. During such interrupts the temperature of the transition region may be first increased then decreased to perform annealing. It is possible to grow the metamorphic transition region structure using a variety of techniques, including metal organic vapour phase epitaxy (MOVPE), molecular beam epitaxy (MBE), atomic layer deposition (ALD), sputtering or plasma deposition. A pulsed MOVPE method is thought to be particularly beneficial for safety and to ensure a high degree of thickness, composition and quality control of the alternating layers 4, 5. Precursor pulsing or growth interrupts between the alternating layers 4,5 would prevent unwanted reactions occurring between the supply gases and/or precursors. Such unwanted reactions could potentially be explosive or lead to the unwanted formation of mixed interface regions with poor crystallinity.

Another embodiment of the invention is concerned with a metamorphic substrate system for the growth of high quality III-Nitride semiconductor devices on silicon wafers. In this case, the supporting substrate is silicon. In order to dispose a high quality III-Nitride device on silicon it is critical to ensure that 2D growth always occurs during the metamorphic transition region deposition and that any growth surface change from 2D to 3D is prevented. The suppression of 3D growth prevents the formation of threading dislocations. FIG. 4 illustrates the multilayer structure of the metamorphic transition region 2. It consists of a series of silicon layers 4 alternating with AlₓGa₁₋ₓN layers 5. In the region of the supporting silicon substrate 1, the thickness of the silicon layers 4 is substantially greater than the AlₓGa₁₋ₓN layers 5. The difference in thickness between the alternating layers is then gradually reduced, in the direction of growth, towards the central region of the metamorphic transition region 2. Above the central region of the metamorphic transition region 2, the thickness of the AlₓGa₁₋ₓN layers 5 gradually becomes greater than the thickness of the silicon layers 4. Finally, in the region of the device 3, the thickness of the AlₓGa₁₋ₓN layers 5 is substantially greater than the silicon layers 4. The structure of the metamorphic substrate system is completed by a layer of AlₓGa₁₋ₓN of any thickness. Varying the thickness of the alternating layers in this way, effectively grades the lattice constant throughout the metamorphic transition region. The value of x can be varied between the layers 5 in order to further control the lattice constant. How this is done depends on the particular top device structure 3 that is intended to be grown over the substrate system, e.g. for an LED top device x is ideally zero at the top of the transition region 2, but if the top device structure is a laser a value for x of approximately 6% at the top of the transition region 2 is preferable.

A III-Nitrides semiconductor device 3 is grown on the top surface of the metamorphic substrate system.

If desired, the structure of FIG. 4 may further include an upper AlₓGa₁₋ₓN layer (not shown) that corresponds to the upper AlₓGa₁₋ₓN layer 5a of FIG. 3.

Since the metamorphic transition region suppresses the formation and propagation of threading dislocations in the growth direction, the III-Nitrides semiconductor device will contain far fewer threading dislocations than in the art, therefore high efficiency device performance will result.

It is not strictly necessary to grow the device 3 using the same technique as used for the metamorphic substrate system. Also it is not strictly necessary to grow the alternating layers 4, 5 immediately in succession; growth interrupts can be provided between layers to ensure smooth interfaces between them and prevent the formation of mixed regions. During such interrupts the temperature of the transition region may be first increased then decreased to perform annealing. It is possible to grow the metamorphic substrate system structure using a variety of techniques, including metal organic vapour phase epitaxy (MOVPE), molecular beam epitaxy (MBE), atomic layer deposition (ALD), sputtering or plasma deposition. A pulsed MOVPE method is thought to be particularly beneficial to ensure a high degree of thickness, composition and quality control of the alternating layers 4, 5. Precursor pulsing or growth interrupts between the alternating layers 4,5 would prevent parasitic reactions occurring between the precursors. Such parasitic reactions could lead to the unwanted formation of mixed interface regions with poor crystallinity.

Although the invention has been shown and described with respect to a certain embodiment or embodiments, equivalent alterations and modifications may occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein exemplary embodiment or embodiments of the invention. In addition, while a particular feature of the invention may have been described above with respect to only one or more of several embodiments, such feature may be combined with one or more other features of the other embodiments, as may be desired and advantageous for any given or particular application.

### Example 1

A description of how to make a metamorphic substrate system which is highly suitable for the growth of high efficiency III-Nitride LED devices with reduced threading dislocations now follows.

A sapphire (Al₂O₃) supporting substrate 1 is first inserted into an MOVPE reactor and thermally cleaned under flowing hydrogen. The MOVPE reactor is equipped with the following gaseous sources: hydrogen, nitrogen, oxygen, ammonia and silane; and the following liquid precursor sources: trimethylgallium (TMG), trimethylindium (TMI), trimethylaluminium (TMA) and bis(cyclopentadienyl)magnesium (Cp2Mg). Following thermal cleaning the supporting substrate is cooled to a temperature suitable for growth of the metamorphic transition region, a temperature in the range 200 to 900° C. is preferred, 500° C. is most preferable. Below 200° C. and above 900° C. the transition region will not easily form. Metamorphic transition region growth can be initiated with either a layer of Al₂O₃ 4 or a layer of AlₓGa₁₋ₓN 5. In the case of the former, the Al₂O₃ layer can have a thickness in the range 1 to 100 nm and is grown by flowing TMA and oxygen alongside nitrogen. In the latter case, there is a large lattice mismatch between the sapphire substrate and AlₓGa₁₋ₓN and therefore it is essential that a 2D growth surface is maintained, i.e. the critical thickness of AlₓGa₁₋ₓN must not be exceeded. Maintaining a 2D surface prevents the formation of threading dislocations. The critical thickness of either AlN or GaN on sapphire is estimated to be approximately 0.3 nm, so the first AlₓGa₁₋ₓN layer must not exceed a thickness of 0.3 nm.

Conversely, the upper layers of the substrate material 4 should have a thickness that is below the critical thickness for the formation of dislocations, while the upper layers of AlGaN 5 may have any desired thickness, for example in the range of 1 to 100 nm.

The following layer thickness sequence, shown in TABLE I, is one example of a layer thickness sequence that can be used to complete the metamorphic transition region. For this example, the AlₓGa₁₋ₓN layers consist of GaN throughout the entire transition region.

TABLE I

| Sequence | Al₂O₃ layer thickness | GaN layer thickness |
|---|---|---|
| number | (nm) | (nm) |
| Start | 5.0 | 0.3 |
| 1 | 4.9 | 0.3 |
| 2 | 4.8 | 0.3 |
| 3 | 4.7 | 0.3 |
| 4 | 4.6 | 0.3 |
| 5 | 4.5 | 0.3 |
| 6 | 4.4 | 0.3 |
| 7 | 4.3 | 0.3 |
| 8 | 4.2 | 0.3 |
| 9 | 4.1 | 0.3 |
| 10 | 4.0 | 0.3 |
| 11 | 3.9 | 0.3 |
| 12 | 3.8 | 0.3 |
| 13 | 3.7 | 0.3 |
| 14 | 3.6 | 0.3 |
| 15 | 3.5 | 0.3 |
| 16 | 3.4 | 0.3 |
| 17 | 3.3 | 0.3 |
| 18 | 3.2 | 0.3 |
| 19 | 3.1 | 0.3 |
| 20 | 3.0 | 0.3 |
| 21 | 2.9 | 0.3 |
| 22 | 2.8 | 0.3 |
| 23 | 2.7 | 0.3 |
| 24 | 2.6 | 0.3 |
| 25 | 2.5 | 0.3 |
| 26 | 2.4 | 0.3 |
| 27 | 2.3 | 0.3 |
| 28 | 2.2 | 0.3 |
| 29 | 2.1 | 0.3 |
| 30 | 2.0 | 0.3 |
| 31 | 1.9 | 0.3 |
| 32 | 1.8 | 0.3 |
| 33 | 1.7 | 0.3 |
| 34 | 1.6 | 0.3 |
| 35 | 1.5 | 0.3 |
| 36 | 1.4 | 0.3 |
| 37 | 1.3 | 0.3 |
| 38 | 1.2 | 0.3 |
| 39 | 1.1 | 0.3 |
| 40 | 1.0 | 0.3 |
| 41 | 0.9 | 0.3 |
| 42 | 0.8 | 0.3 |
| 43 | 0.7 | 0.3 |
| 44 | 0.6 | 0.3 |
| 45 | 0.5 | 0.3 |
| 46 | 0.4 | 0.4 |
| 47 | 0.3 | 0.5 |
| 48 | 0.3 | 0.6 |
| 49 | 0.3 | 0.7 |
| 50 | 0.3 | 0.8 |
| 51 | 0.3 | 0.9 |
| 52 | 0.3 | 1.0 |
| 53 | 0.3 | 1.1 |
| 54 | 0.3 | 1.2 |
| 55 | 0.3 | 1.3 |
| 56 | 0.3 | 1.4 |
| 57 | 0.3 | 1.5 |
| 58 | 0.3 | 1.6 |
| 59 | 0.3 | 1.7 |
| 60 | 0.3 | 1.8 |
| 61 | 0.3 | 1.9 |
| 62 | 0.3 | 2.0 |
| 63 | 0.3 | 2.1 |
| 64 | 0.3 | 2.2 |
| 65 | 0.3 | 2.3 |
| 66 | 0.3 | 2.4 |
| 67 | 0.3 | 2.5 |
| 68 | 0.3 | 2.6 |
| 69 | 0.3 | 2.7 |
| 70 | 0.3 | 2.8 |
| 71 | 0.3 | 2.9 |
| 72 | 0.3 | 3.0 |
| 73 | 0.3 | 3.1 |
| 74 | 0.3 | 3.2 |
| 75 | 0.3 | 3.3 |
| 76 | 0.3 | 3.4 |
| 77 | 0.3 | 3.5 |
| 78 | 0.3 | 3.6 |
| 79 | 0.3 | 3.7 |
| 80 | 0.3 | 3.8 |
| 81 | 0.3 | 3.9 |
| 82 | 0.3 | 4.0 |
| 83 | 0.3 | 4.1 |
| 84 | 0.3 | 4.2 |
| 85 | 0.3 | 4.3 |
| 86 | 0.3 | 4.4 |
| 87 | 0.3 | 4.5 |
| 88 | 0.3 | 4.6 |
| 89 | 0.3 | 4.7 |
| 90 | 0.3 | 4.8 |
| 91 | 0.3 | 4.9 |
| 92 | 0.3 | 5.0 |

In the sequence of layers in Table 1, in the pairs below the middle pair (ie pairs up to pair 45, which are nearer the substrate 1 than the device 3, the AlₓGa₁₋ₓN layer (in this example the GaN layer) has a thickness less than the critical thickness for the formation of threading dislocations. Similarly, in the pairs above the middle pair (ie pair 47 and above, which are nearer the device 3 than the substrate 1) the layer of material of the same general chemical composition of the substrate (in this example the Al₂O₃ layer) has a thickness less than the critical thickness for the formation of threading dislocations.

Furthermore, both layers of the middle pair (46) of layers have a thickness less than the critical thickness for formation of threading dislocations, even though they each have a thickness of 0.4 nm. The critical thickness of each layer will change with increasing pair number, as a consequence of the lattice parameter gradually changing from through the metamorphic transition region, from that of the substrate into that of the top layer.

To prevent any explosive or parasitic reactions between source gases or precursors occurring, growth interruptions are applied between the deposition of layers to allow any gases to be pumped away, for example, to prevent oxygen reacting with hydrogen, which is a potentially explosive mixture.

During the growth interruptions, it is also possible to introduce an anneal to the metamorphic transition region where its temperature is increased above 700° C. before cooling down for growth of the next layer in the sequence. Such anneal sequences can help to flatten the growth surface and further reduce the number of threading dislocations.

After the growth of the final alternating layer of the metamorphic transition region, an upper AlGanN layer 5a may be deposited if desired, and the substrate can be heated to temperatures in excess of 900° C. for the growth of a device 3 which may be any high efficiency III-nitrides device.

### Example 2

Another description of how to make a metamorphic substrate system which is highly suitable for the growth of high efficiency III-Nitride LED devices with reduced threading dislocations now follows.

A silicon (Si) supporting substrate 1 is first inserted into an MOVPE reactor and thermally cleaned under flowing hydrogen. The MOVPE reactor is equipped with the following gaseous sources: hydrogen, nitrogen, ammonia and silane; and the following liquid precursor sources: trimethylgallium (TMG), trimethylindium (TMI), trimethylaluminium (TMA) and bis(cyclopentadienyl)magnesium (Cp2Mg). Following thermal cleaning the supporting substrate is cooled to a temperature suitable for growth of the metamorphic transition region, a temperature in the range 200 to 1000° C. is preferred, 900° C. is most preferable. Below 200° C. the transition region will not easily form. Metamorphic transition region growth can be initiated with either a layer of Si 4 or a layer of AlₓGa₁₋ₓN 5. In the case of the former, the Si layer can have a thickness in the range 1 to 100 nm and is grown by flowing silane alongside hydrogen. In the latter case, there is a large lattice mismatch between the silicon substrate and AlₓGa₁₋ₓN therefore it is essential that a 2D growth surface is maintained, i.e. the critical thickness of AlₓGa₁₋ₓN must not be exceeded. Maintaining a 2D surface prevents the formation of threading dislocations. The critical thickness of AlN or GaN on silicon is estimated to be approximately 0.3 nm, so the first AlₓGa₁₋ₓN layer must not exceed a thickness of 0.3 nm. For this example, the AlₓGa₁₋ₓN layers consist of GaN throughout the entire metamorphic transition region. The same layer thickness sequence as shown in TABLE I may be used to complete the metamorphic transition region.

To prevent any parasitic reaction between source gases or precursors occurring, growth interruptions can be applied between the deposition of layers to allow any gases to be pumped away, for example, to prevent silane reacting with ammonia which causes non-crystalline silicon nitride to be formed.

After the growth of the final alternating layer of the metamorphic transition region, an upper AlGanN layer 5a may be deposited if desired, and the substrate can be heated to temperatures in excess of 900° C. for the growth of a device 3 which may be any high efficiency III-nitrides device.

It should be understood that the embodiments described above are only example of the invention and that the invention may be embodied in other ways. For example, the layer thickness sequence of Table 1 is only one example, and the invention is not limited to this layer thickness sequence nor even to a sequence of 92 pairs of layers. In principle the invention may be applied with only 2 pairs of layers (so that the transition region 2 has the structure M, AlGaN, M, AlGaN or the structure AlGaN, M, AlGaN, M) but better results are expected with a greater number of pairs of layers, for example 50-150 pairs of layers or 70-110 pairs of layers.

As a further example, the invention is not limited to the specific materials used in the examples described above. As noted above, other suitable materials for the supporting substrate 1 include silicon carbide and gallium arsenide (GaAs), and the present invention may be applied using a supporting substrate 1 formed of silicon carbide or gallium arsenide (GaAs). That is, a further example of the invention is a substrate system comprising a silicon carbide substrate and a metamorphic transition region disposed on a surface of the silicon carbide substrate, the metamorphic transition region including a plurality of alternating layers of AlₓGa₁₋ₓN (0≦x≦1) and silicon carbide. A yet further example of the invention is a substrate system comprising a gallium arsenide (GaAs) substrate and a metamorphic transition region disposed on a surface of the gallium arsenide substrate, the metamorphic transition region including a plurality of alternating layers of AlₓGa₁₋ₓN (0≦x≦1) and gallium arsenide (GaAs).

Note that the present invention may also be expressed as below. The substrate system may further comprise an upper layer of AlₓGa₁₋ₓN disposed over the metamorphic transition region.

Said metamorphic transition region may comprise a superlattice.

The layers of the material having the same general chemical composition as the substrate material may generally decrease in thickness away from the substrate.

The layer of the material having the same general chemical composition as the substrate material furthest from the substrate may have a thickness less than the critical thickness for formation of dislocations.

The layers of AlₓGa₁₋ₓN may generally increase in thickness away from the substrate.

The layer of AlₓGa₁₋ₓN closest to the substrate may have a thickness less than the critical thickness for formation of dislocations. (As is well known, if a thin layer of a material is disposed over a substrate having a different lattice constant to the lattice constant of the material, a strained-layer structure may exist in which the thin layer adopts the lattice constant of the substrate; if this happens, dislocations do not form at the interface between the material and substrate. This effect occurs because, for a low thickness of the layer, the elastic strain energy arising from the lattice mis-match is less than the energy required for a dislocation to form, and strained-layer structure will be energetically stable against dislocation formation. However, at larger thicknesses of the layer, the layer will adopt its intrinsic lattice constant and dislocations will occur at the interface. The strained-layer structure can exist provided that the thickness of the material layer is below a certain thickness—known as the critical thickness for formation of dislocations or just the “critical thickness”.)

Said substrate and said upper AlₓGa₁₋ₓN layer (or the uppermost AlₓGa₁₋ₓN layer of the transition region if the upper AlₓGa₁₋ₓN layer (eg layer 5a of FIG. 3) is not provided) may have different crystal systems. The invention allows a good quality upper AlₓGa₁₋ₓN layer to be grown over the substrate, even if the substrate and AlₓGa₁₋ₓN have different crystal systems to one another.

Said metamorphic transition region may contain threading dislocations, and the number density of the threading dislocations may decrease along the growth direction.

Said upper AlₓGa₁₋ₓN layer (or the uppermost AlₓGa₁₋ₓN layer of the transition region if the upper AlₓGa₁₋ₓN layer (eg layer 5a of FIG. 3) is not provided) may contain fewer than 10⁷ threading dislocations per cm².

Said upper AlₓGa₁₋ₓN layer (or the uppermost AlₓGa₁₋ₓN layer of the transition region if the upper AlₓGa₁₋ₓN layer (eg layer 5a of FIG. 3) is not provided) may contain fewer than 10⁶ threading dislocations per cm².

Said upper AlₓGa₁₋ₓN layer (or the uppermost AlₓGa₁₋ₓN layer of the transition region if the upper AlₓGa₁₋ₓN layer (eg layer 5a of FIG. 3) is not provided) may contain fewer than 10⁵ threading dislocations per cm².

Said metamorphic transition region may have a lattice constant which, adjacent to the substrate, is substantially equal to the lattice constant of the substrate and which, adjacent to the upper AlₓGa₁₋ₓN layer, is substantially equal to the lattice constant of the upper AlₓGa₁₋ₓN layer.

Said plurality of alternating layers may contain a plurality of layers of Al₂O₃ and the substrate material M may be sapphire.

Said plurality of alternating layers may contain a plurality of layers of silicon and the substrate material may be silicon.

Said plurality of alternating layers may contain a plurality of layers of GaAs and the substrate material may be GaAs.

Said plurality of alternating layers may contain a plurality of layers of silicon carbide and the substrate material may be silicon carbide.

The substrate may be a crystalline substrate.

The metamorphic transition region may be deposited using one of MOVPE, MBE, ALD, sputtering or plasma deposition.

A third aspect of the invention provides a substrate system manufactured by a method of the second aspect.

A fourth aspect of the invention provides a III-Nitrides semiconductor device comprising a substrate system of the first or third aspect. The device may for example comprise one or more layers of III-Nitride semiconductor material grown over the substrate system. The device may for example be an optoelectronic semiconductor device such as, for example, a light emitting diode (LED), laser diode (LD) or a solar cell, or an electronic semiconductor device such as, for example, a heterostructure field effect transistor (HFET) or a high electron mobility transistor (HEMT).

### INDUSTRIAL APPLICABILITY

The invention makes possible the growth of higher quality layer(s) of III-Nitride semiconductor material(s) over a foreign substrate such as sapphire, GaAs, silicon or silicon carbide. This makes possible the fabrication of higher-quality III-Nitride semiconductor devices such as, for example, LEDs emitting in the blue region of the spectrum or other semiconductor devices

1. A substrate system comprising:
a substrate made of a substrate material;
a metamorphic transition region disposed on a surface of the substrate, the metamorphic transition region including a plurality of alternating layers of AlₓGa₁₋ₓN (0≦x≦1) and a material having the same general chemical composition as the substrate material.

2. A substrate system as claimed in claim 1, and further comprising a upper layer of AlₓGa₁₋ₓN disposed over the metamorphic transition region.

3. A substrate system as claimed in claim 1, wherein said metamorphic transition region comprises a superlattice.

4. A substrate system as claimed in claim 1 wherein the layers of the material having the same general chemical composition as the substrate material generally decrease in thickness away from the substrate.

5. A substrate system as claimed in claim 1 wherein the layer of the material having the same general chemical composition as the substrate material furthest from the substrate has thickness less than the critical thickness for formation of dislocations.

6. A substrate system as claimed in claim 1 wherein the layers of AlₓGa₁₋ₓN generally increase in thickness away from the substrate.

7. A substrate system as claimed in claim 1 wherein the layer of AlₓGa₁₋ₓN closest to the substrate has a thickness less than the critical thickness for formation of dislocations.

8. A substrate system as claimed in claim 2 wherein said substrate and said upper AlₓGa₁₋ₓN layer have different crystal systems.

9. A substrate system as claimed in claim 1 wherein said metamorphic transition region contains threading dislocations, and wherein the number density of the threading dislocations decreases along the growth direction.

10. A substrate system as claimed in claim 2 wherein said upper AlₓGa₁₋ₓN layer contains fewer than 10⁷ threading dislocations per cm².

11. A substrate system as claimed in claim 2 wherein said upper AlₓGa₁₋ₓN layer contains fewer than 10⁶ threading dislocations per cm².

12. A substrate system as claimed in claim 2 wherein said upper AlₓGa₁₋ₓN layer contains fewer than 10⁵ threading dislocations per cm².

13. A substrate system as claimed in claim 1 wherein said metamorphic transition region has a lattice constant which, adjacent to the substrate, is substantially equal to the lattice constant of the substrate and which, adjacent to the upper AlₓGa₁₋ₓN layer, is substantially equal to the lattice constant of the upper AlₓGa₁₋ₓN layer.

14. A substrate system as claimed in claim 1 wherein said plurality of alternating layers contains a plurality of layers of Al₂O₃ and the substrate material is sapphire.

15. A substrate system as claimed in claim 1 wherein said plurality of alternating layers contains a plurality of layers of silicon and the substrate material is silicon.

16. A substrate system as claimed in claim 1 wherein said plurality of alternating layers contains a plurality of layers of GaAs and the substrate material is GaAs.

17. A substrate system as claimed in claim 1 wherein said plurality of alternating layers contains a plurality of layers of silicon carbide and the substrate material is silicon carbide.

18. A method of forming a substrate system comprising the steps of:
providing a substrate made of a substrate material
depositing a metamorphic transition region on the surface of the said supporting substrate, the metamorphic transition region including a plurality of alternating layers of AlₓGa₁₋ₓN (0≦x≦1) and a material having the same general chemical composition as the substrate material.

19. A method as claimed in claim 18 and further comprising depositing a layer of AlₓGa₁₋ₓN on said metamorphic transition region.

20. A method as claimed in claim 18 wherein the metamorphic transition region is deposited using one of metal organic vapour phase epitaxy MOVPE, molecular beam epitaxy MBE, atomic layer deposition ALD, sputtering or plasma deposition.

21. A substrate system manufactured by a method as defined in claim 18.

22. A III-Nitrides semiconductor device comprising a substrate system as defined in claim 1.
